(19) United States
(12) Patent Application Publication
(10) Pub. No.: US 2011/0253189 A1
(43) Pub. Date: Oct. 20, 2011

(54) THIN-FILM SOLAR CELL

(75) Inventors: Makoto Shimosawa, Arao-city (JP); Nobuyuki Masuda, Tamana-city (JP)

(73) Assignee: FUJI ELECTRIC SYSTEMS CO., LTD., Tokyo (JP)

(21) Appl. No.: 12/978,104

(22) Filed: Dec. 23, 2010

(30) Foreign Application Priority Data
Apr. 20, 2010 (JP) 2010-096668
Aug. 30, 2010 (JP) 2010-192022

(51) Int. Cl. H01L 31/05

(52) U.S. Cl. 136/244

(57) ABSTRACT

A thin-film solar cell includes an insulating substrate and multiple unit solar cells. Each unit solar cell includes a photoelectric conversion portion having a first electrode layer, a photoelectric conversion layer, and a second transparent electrode layer, formed on a front surface of the insulating substrate, and a rear electrode layer formed on a rear surface of the insulating substrate. A portion of the first electrode layer of a first unit solar cell, taken from a plan view, overlaps an extending portion of the rear electrode layer of an adjacent second unit solar cell. The first electrode layer of the first unit solar cell is electrically connected to the rear electrode layer of the adjacent second unit solar cells via at least one connection hole passing through the insulating substrate and being connected to the extending portion.

### CROSS-REFERENCE TO RELATED APPLICATION

This application claims priority under 35 U.S.C. §119 from Japanese Patent Application No. 2010-096668, filed on Apr. 20, 2010, and Japanese Patent Application, filed on Aug. 30, 2010, the entirety of which is incorporated herein by reference.

### BACKGROUND OF THE INVENTION

1. Field of the Invention

The present invention relates to a solar cell that uses sunlight to generate power and more particularly, to a thin-film solar cell having a structure in which multiple unit solar cells (unit cells) are connected in series to one another.

2. Description of the Related Art

In recent years, solar cells have drawn attention as one of means for solving global environmental problems. Among the solar cells, a solar cell including a photoelectric conversion layer made of amorphous silicon, microcrystalline silicon, a compound, such as cadmium telluride (CdTe) or copper-indium-gallium-selenide (CIGC), or an organic material has an advantage of being able to significantly reduce the amount of material used, as compared to other types of solar cells according to the related art. The reason is that the thin photoelectric conversion layer, in such solar cell, can be realized in a thin film having a thickness of about several hundreds of nanometers (nm) to several micrometers (μm). Therefore, such solar cell has drawn attention from the view point of a low manufacturing cost. This solar cell is called a thin-film solar cell. In addition, a further advantage of the thin-film solar cell is that the thin-film solar cell can be formed on various kinds of substrates, unlike the crystalline silicon solar cell according to the related art.

Since the voltage generated by a single solar cell is low, a structure is generally used in which multiple unit solar cells (unit cells) are connected in series to one another to increase the generated voltage. In the case of the thin-film solar cell, in general, an electrode layer and a photoelectric conversion layer are formed on one substrate and each of the formed layers is divided into multiple unit cells by, for example, laser patterning, thereby achieving a structure in which the unit cells are connected in series to one another. For example, Japanese Patent Application Laid-Open (JP-A) No. 10-233517 discloses a thin-film solar cell in which multiple unit cells are formed on a sheet (film) substrate and the unit cells are connected in series to one another by current collection holes and connection holes passing through the sheet (film) substrate. The solar cell structure is called a Series-Connection through Apertures formed on Film (SCAF) structure.

FIG. 9 is a plan view illustrating a thin-film solar cell having the SCAF structure according to the related art, and FIGS. 10A to 10G are cross-sectional views (corresponding to cross-sectional views taken along the line X-X of FIG. 9) illustrating a process sequence of a method of manufacturing the thin-film solar cell having the SCAF structure according to the related art. In FIGS. 10A to 10G, the electrode layers that come to have the same potential, when the thin-film solar cell receives light and generates power, are hatched in the same manner.

As illustrated in FIG. 9 and FIGS. 10A to 10G, a thin-film solar cell 70 includes an insulating substrate 71. A photoelectric conversion portion 75 including a first electrode layer 72, a photoelectric conversion layer 73, and a second electrode layer 74 stacked in this order, is provided on the front surface of the insulating substrate 71, and a rear electrode layer 78 including a third electrode layer 76 and a fourth electrode layer 77 stacked in this order, is provided on the rear surface of the insulating substrate 71. In the thin-film solar cell 70 illustrated in FIG. 9 and FIGS. 10A to 10G, the first electrode layer 72 and the photoelectric conversion layer 73 are formed in the same range of the front surface of the insulating substrate 71, and the third electrode layer 76 and the fourth electrode layer 77 are formed in the same range of the rear surface of the insulating substrate 71.

In addition, each end of the front surface of the insulating substrate 71 in the horizontal direction of FIG. 9 is provided with a portion having a double layer structure of the first electrode layer 72 and the photoelectric conversion layer 73. The entire central portion other than the two double layer portions is further provided with the second electrode layer 74 stacked on the photoelectric conversion layer 73. That is, the central portion is provided with the photoelectric conversion portion 75 having a triple layer structure of the first electrode layer 72, the photoelectric conversion layer 73, and the second electrode layer 74.

Each layer on the front surface and the rear surface of the insulating substrate 71 is linearly removed and divided into multiple portions to form unit cells (UCs), each having a unit portion (hereinafter, referred to as a “unit photoelectric conversion portion”) of the photoelectric conversion portion 75 and a unit portion (hereinafter, referred to as a “unit rear electrode portion”) of the rear electrode layer 78, on the insulating substrate 71.

In each of the unit cells (UCs), the second electrode layer 74 and the rear electrode layer 78 (the third electrode layer 76 and the fourth electrode layer 77) are electrically connected to each other through current collection holes 79. A first linearly removed portion 81 for forming the unit photoelectric conversion portion on the front surface of the insulating substrate 71 is misaligned in position by a predetermined distance with a second linearly removed portion 82 for forming the unit rear electrode portion on the rear surface of the insulating substrate 71, with the insulating substrate 71 interposed therebetween. Therefore, of two adjacent unit cells (UCs), a portion of one unit cell (UCₙ) in which the connection holes 80 are provided, is electrically connected to the second electrode layer 74 of the other unit cell (UCₙ₊₁) via the current collection holes 79, at a position of the rear electrode layer 78 being opposite to the second electrode layer 74 across the insulating substrate 71 interposed therebetween. In this way, the unit cell (UCₙ) can be electrically connected in series to an adjacent unit cell (UCₙ₊₁) via the connection holes 80 and the rear electrode layer 78.

Next, the method of manufacturing the thin-film solar cell according to the related art will be described according to the process sequence with reference to FIGS. 10A to 10G. First, as illustrated in FIG. 10A, multiple connection holes 80 are formed in the insulating substrate 71 at predetermined positions. As the insulating substrate 71, for example, a polyimide-based film, a polyethylene naphthalate (PEN)-based film, a polyether sulfone (PES)-based film, a polyethylene terephthalate (PET)-based film, or an aramid-based film may be used. Each of The connection holes 80 is circular in shape and 1 mm in diameter. The connection holes 80 may be formed by a mechanical method such as punching.

Then, as illustrated in FIG. 10B, the first electrode layer 72 is formed on the front surface of the insulating substrate 71, and then the third electrode layer 76 is formed on the rear surface of the insulating substrate 71. For this instance, the first electrode layer 72 and the third electrode layer 76 overlap each other so as to be electrically connected each other on the inner circumferential surface of the connection hole 80.

Then, as illustrated in FIG. 10C, multiple current collection holes 79 are formed in the insulating substrate 71. Similar to the connection holes 80, each of the current collection holes 79 is circular in shape and 1 mm in diameter. The current collection holes 79 may be formed by a mechanical method such as punching.

Then, as illustrated in FIG. 10D, the photoelectric conversion layer 73 is formed on the first electrode layer 72. The photoelectric conversion layer 73 is a thin semiconductor layer. For example, an amorphous silicon (a-Si) film may be used as the photoelectric conversion layer 73.

Then, as illustrated in FIG. 10E, the second electrode layer 74 is formed on the photoelectric conversion layer 73. The second electrode layer 74 is a transparent electrode layer. For example, an indium tin oxide (ITO) film may be used as the second electrode layer 74. When the second electrode layer 74 is formed, the connection holes 80 and peripheral regions thereof are covered with a mask so that the second electrode layer 74 is not formed in portions at which the connection holes 80 are formed.

Then, as illustrated in FIG. 10F, the fourth electrode layer 77 is formed on the third electrode layer 76 which is formed on the rear surface of the insulating substrate 71. The fourth electrode layer 77 is a low-resistance conductive layer. For example, a low-resistance metal film may be used as the fourth electrode layer 77. In this case, the second electrode layer 74 and the fourth electrode layer 77 overlap each other so as to be electrically connected to each other on the inner circumferential surface of the current collection hole 79.

Through the above described processes, the photoelectric conversion portion 75 in which the first electrode layer 72, the photoelectric conversion layer 73, and the second electrode layer 74 are stacked is formed on the front surface of the insulating substrate 71. Also, the rear electrode layer 78 in which the third electrode layer 76 and the fourth electrode layer 77 are stacked is formed on the rear surface of the insulating substrate 71.

Then, as illustrated in FIG. 10G, each layer formed on the front surface of the insulating substrate 71 is linearly removed to form the first linearly removed portion 81, and each layer formed on the rear surface of the insulating substrate 71 is linearly removed to form the second linearly removed portion 82. In this way, the photoelectric conversion portion 75 formed on the front surface of the insulating substrate 71 and the rear electrode layer 78 formed on the rear surface of the insulating substrate 71 are divided into multiple unit portions, and thus multiple unit cells (UC), each having a unit portion (unit photoelectric conversion portion) of the photoelectric conversion portion 75 and a unit portion (unit rear electrode layer) of the rear electrode layer, is formed on the insulating substrate 71. As described above, in each of the unit cells (UC), the second electrode layer 74 and the fourth electrode layer 77 (that is, the rear electrode layer 78) can be electrically connected to each other through the current collection holes 79, and the first electrode layer 72 of one unit cell (UCₙ) of two adjacent unit cells (UCs) can be electrically connected to the third electrode layer 76 (that is, the rear electrode layer 78) of the other unit cell (UCₙ₊₁) through the connection hole 80.

When light is emitted to the thin-film solar cell 70 and carriers (electrons and holes) are generated in the photoelectric conversion layer 73 of each unit cell (UC), one kind of carriers flow to the second electrode layer (transparent electrode layer) 74 by the electric field in the p-n junction. Since the second electrode layer 74 is electrically connected to the fourth electrode layer 77 (the rear electrode layer 78) on the inner circumferential surface of the current collection hole 79, the carriers that have flowed to the second electrode layer 74 further move to the rear surface of the insulating substrate 71 via the current collection hole 79. Since the photoelectric conversion layer 73 can be substantially regarded as an insulating layer, the first electrode layer 72 and the second electrode layer 74 are substantially insulated from each other. The carriers that have moved to the rear surface of the insulating substrate 71 still further move to the connection hole 80. The second electrode layer 74 is not formed in a portion in which the connection hole 80 is formed, and the first electrode layer 72 and the third electrode layer 76 (the rear electrode layer 78) are electrically connected to each other on the inner circumferential surface of the connection hole 80. Therefore, the carriers yet further move to the front surface of the insulating substrate 71 via the connection hole 80. Then, the carriers move to the photoelectric conversion layer 73 of an adjacent unit cell (UC) on the front surface of the insulating substrate 71. As such, in the thin-film solar cell 70 having the SCAF structure according to the related art, multiple unit cells (UCs) are connected in series to one another via the current collection holes 79 and the connection holes 80.

In the thin-film solar cell according to the related art, in each unit cell, the second electrode layer, which is a transparent electrode layer, and the rear electrode layer are electrically connected to each other through the current collection holes, and the power loss (current collection loss) of the transparent electrode layer with high resistance is reduced a little.

However, in the thin-film solar cell according to the related art, as illustrated in FIG. 9, the unit photoelectric conversion portion and the unit rear electrode layer forming each unit cell (UC) deviate from each other in the direction (the vertical direction of FIG. 9) in which the unit cells are arranged, and the positions where the current collection holes and the connection holes in each unit cell (UC) are formed, are limited. Therefore, the positions where the current collection holes and the connection holes are formed, are not optimized in terms of power collection efficiency. Therefore, the thin-film solar cell needs to be improved.

### SUMMARY OF THE INVENTION

The invention has been made in order to solve the above-mentioned problems and an object of the invention is to provide a thin-film solar cell capable of preventing positions where current collection holes and connection holes are formed from being limited and of reducing power loss, as compared to the related art.

According to an aspect of the invention, a thin-film solar cell includes multiple unit solar cells that are formed on an insulating substrate. Each of the multiple unit solar cells includes a photoelectric conversion portion that includes a first electrode layer, a photoelectric conversion layer, and a second transparent electrode layer sequentially formed on a front surface of the insulating substrate, and a rear electrode layer that is formed on a rear surface of the insulating substrate. The second electrode layer and the rear electrode layer are electrically connected to each other by multiple current collection holes passing through the insulating substrate in each of the unit solar cells. At least one of the first electrode layer and the rear electrode layer includes an extending portion so that a portion of the first electrode layer of one of two adjacent unit solar cells overlaps a portion of the rear electrode layer of the other unit solar cell with the insulating substrate interposed therebetween. In the overlap region, the first electrode layer of one of the two adjacent unit solar cells is electrically connected to the rear electrode layer of the other unit solar cell through at least one connection hole passing through the insulating substrate, such that the multiple unit solar cells are connected in series to one other.

A region in which the second electrode layer is not formed may be provided in the vicinity of a portion in which the connection holes are formed, and the extending portion may be disposed in the region in which the second electrode layer is not formed. The second electrode layer may include a first region in which the connection holes are provided and a second region in which the current collection holes are provided. The first region may be electrically isolated from the second region, and the extending portion may be disposed in the first region.

The current collection holes may be distributed all over the second electrode layer of each of the unit solar cells. In this case, it is preferable that the multiple current collection holes be arranged in a houndstooth pattern. In this way, the multiple current collection holes are substantially uniformly distributed in the second electrode layer in each of the unit solar cells.

In the unit solar cell according to the above-mentioned aspect, each layer formed on the front surface and the rear surface of the insulating substrate may be linearly removed and divided into multiple portions each having a unit photoelectric conversion portion and a unit rear electrode portion. The dividing scheme of each layer into multiple portions may be not necessarily the linear form, but the division is achieved using a mask during manufacture.

The extending portion formed in at least one of the first electrode layer and the rear electrode layer may be formed as a bent portion.

According to the thin-film solar cell of the above-mentioned aspect of the invention, at least one of the first electrode layer formed on the front surface of the insulating substrate and the rear electrode layer formed on the rear surface of the insulating substrate includes the extending portion in each unit solar cell. Therefore, the positions where the unit photoelectric conversion portion and the unit rear electrode layer forming the unit solar cell are optimized. As a result, it is possible that the current collection holes or the connection holes be formed at desired positions in each unit solar cell.

The region in which the second electrode layer is not formed is provided in the vicinity of a portion in which the connection holes are formed, and the bent portion is disposed in the region in which the second electrode layer is not formed. Alternatively, the second electrode layer is formed so as to be electrically isolated from the first region in which the connection holes are provided and the second region in which the connection hole is not provided, and the bent portion is arranged in the first region. According to this structure, during the processing for forming the bent portion, for example, even when the photoelectric conversion layer is damaged, there is no risk that a leakage path is formed due to the electrical connection between the first electrode layer and the second electrode layer. Therefore, it is possible that a reduction in the output of the thin-film solar cell that is attributable to the process of removing each layer is prevented.

When multiple current collection holes are arranged so as to be distributed all over the second electrode layer of each unit solar cell, it is possible to shorten the path of a current flowing through the second electrode layer with high resistance and improve the uniformity of current flow. This can result in a significant reduction in power loss.

### BRIEF DESCRIPTION OF THE DRAWINGS

FIG. 1 is a plan view illustrating a thin-film solar cell according to a first embodiment of the invention;

FIG. 2 is a plan view illustrating a thin-film solar cell according to a second embodiment of the invention;

FIG. 3 includes exploded perspective views (a) to (d) illustrating the thin-film solar cell according to the second embodiment of the invention;

FIG. 4 is a cross-sectional view taken along the line IV-IV of FIG. 2;

FIG. 5 is a plan view illustrating a thin-film solar cell according to a third embodiment of the invention;

FIG. 6 is a plan view illustrating a thin-film solar cell according to a fourth embodiment of the invention;

FIG. 7 is a cross-sectional view taken along the line VII-VII of FIG. 6;

FIG. 8 is a plan view illustrating a thin-film solar cell according to a fifth embodiment of the invention;

FIG. 9 is a plan view illustrating a thin-film solar cell according to the related art; and

FIGS. 10A to 10G are diagrams illustrating a process sequence of a method of manufacturing the thin-film solar cell according to the related art and correspond to the cross-sectional view of FIG. 9 taken along the line X-X.

### DESCRIPTION OF THE PREFERRED EMBODIMENTS

Hereinafter, exemplary embodiments of the invention will be described with reference to the accompanying drawings. It should be kept in mind that the following described embodiments are only presented by way of example and should not be construed as limiting the inventive concept to any particular configuration.

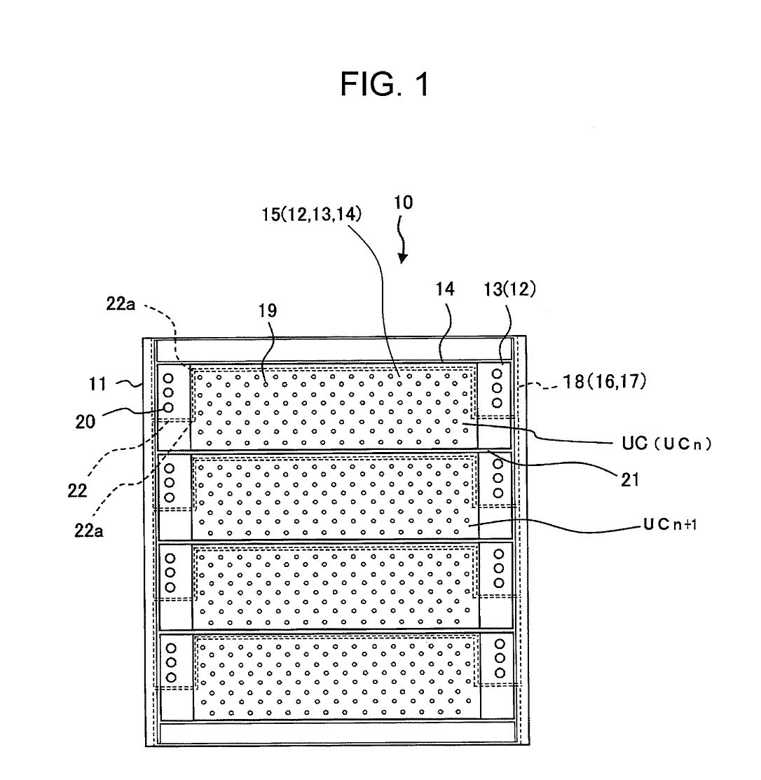

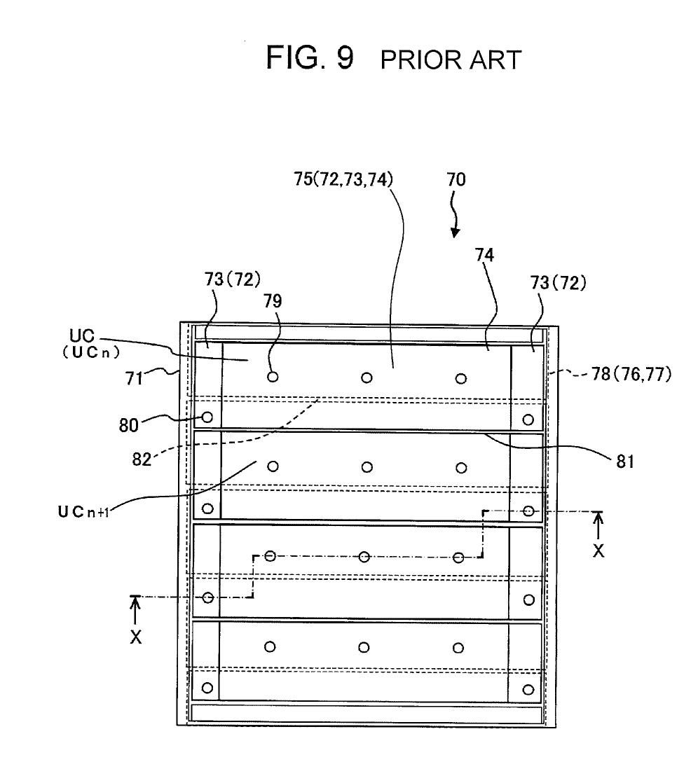

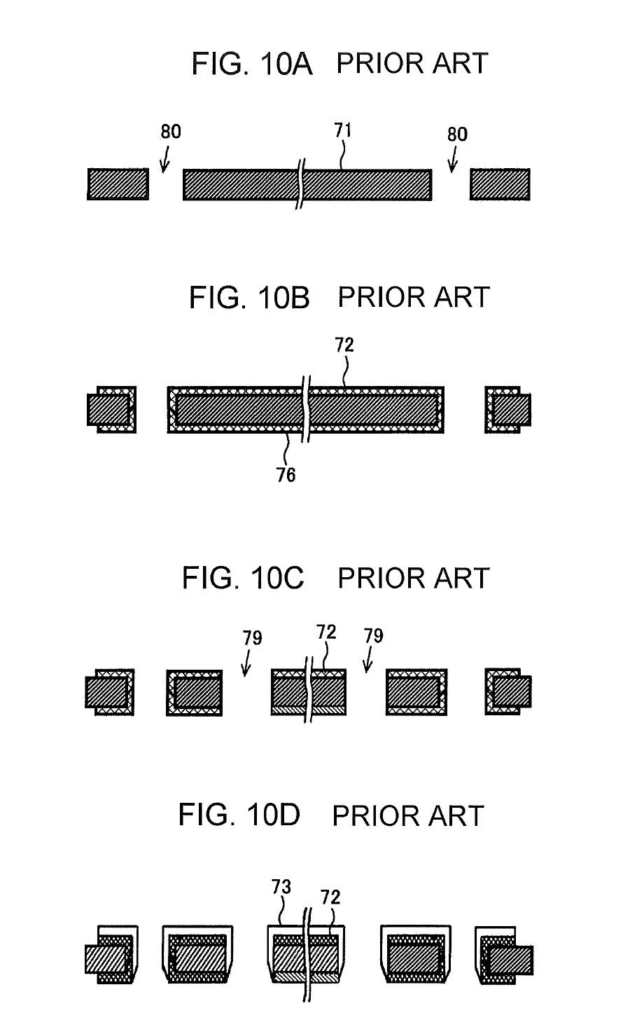

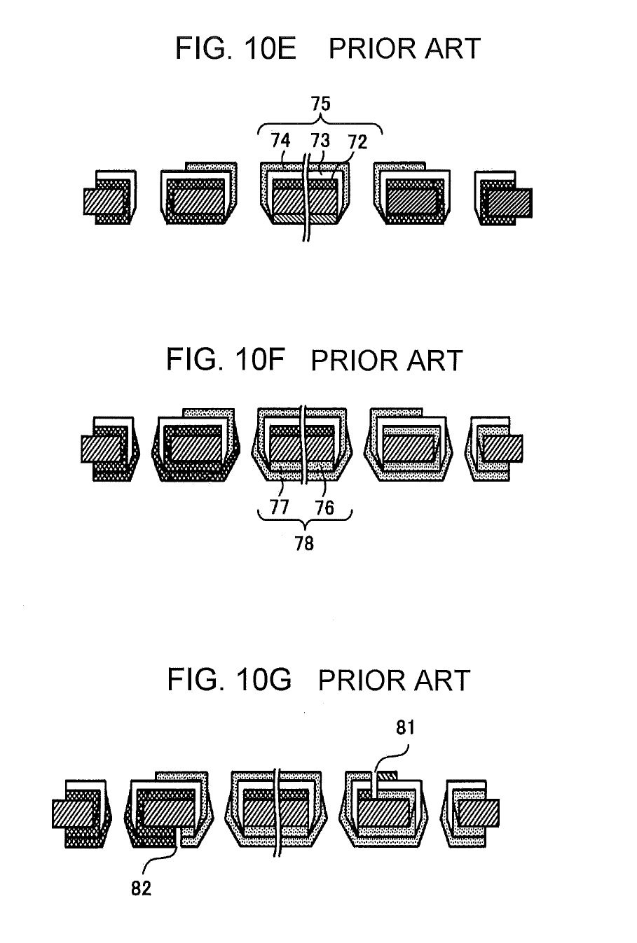

FIG. 1 is a plan view illustrating a thin-film solar cell 10 according to a first embodiment of the invention. The thin-film solar cell 10 has an SCAF structure, and the basic structure of the thin-film solar cell 10 is the same as that of the thin-film solar cell 70 according to the related art illustrated in FIGS. 9 and 10. That is, the thin-film solar cell 10 includes a flexible insulating substrate 11. A photoelectric conversion portion 15 having a first electrode layer 12, a photoelectric conversion layer 13, and a second electrode layer 14 sequentially stacked is provided on the front surface of the insulating substrate 11, and a rear electrode layer 18 having a third electrode layer 16 and a fourth electrode layer 17 sequentially stacked is provided on the rear surface of the insulating substrate 11.

Each of the layers provided on the front and rear surfaces of the insulating substrate 11 is linearly removed and divided into multiple portions by, for example, a laser patterning process. In this way, multiple unit solar cells (unit cells: UCs), each having a unit photoelectric conversion portion and a unit rear electrode portion, are formed in the insulating substrate 11. In each of the layers provided on the front surface of the insulating substrate 11, the linearly removed portion corresponds to a first linearly removed portion 21. In each of the layers of the rear surface of the insulating substrate 11, the linearly removed portion corresponds to a second linearly removed portion 22.

As such, in this embodiment, each of the layers provided on the front and rear surfaces of the insulating substrate is linearly removed and divided into multiple portions to form the unit solar cells each having the unit photoelectric conversion portion and the unit rear electrode portion. However, the method of dividing each layer into multiple portions is not limited thereto. When a film is formed, a mask may be used to provide the divided portions. In addition, the shape of the isolating portion does not need to be a line, but the isolating portion may have any shape as long as it can electrically isolate the layer.

In each unit cell (UC), the second electrode layer 14 and the fourth electrode layer 17 are electrically connected to each other via multiple current collection holes 19. Of two adjacent unit cells (UCs), a series connection portion of the first electrode layer 12 in part of one unit cell (UCₙ) in which connection holes 20 are provided is electrically connected to an extending portion. The extending portion is formed as a bent portion of the third electrode layer 16, in the other unit cell (UCₙ₊₁) via the connection holes 20. In this way, the series connection structure of each unit cell (UC) is formed. The series connection portion of the first electrode layer 12 in the unit cell (UC) means a region (that is, a region that does not have a three-layer structure) that does not have the photoelectric conversion portion 15 in the first electrode layer 12 formed on the front surface of the substrate, or a portion of the region. The extending portion of the third electrode layer 16 in the unit cell (UC) means a region of the third electrode layer 16 formed on the rear surface of the substrate, other than the region corresponding to the photoelectric conversion portion 15 formed on the front surface of the substrate, or a portion of the region.

Next, each component of the thin-film solar cell 10 will be described. For example, a polyimide-based film, a polyethylene naphthalate (PEN)-based film, a polyether sulfone (PES)-based film, a polyethylene terephthalate (PET)-based film, or an aramid-based film may be used as a plastic substrate, which corresponds to the insulating substrate 11. When flexibility is not necessary, a glass substrate, for example, may be used.

The first electrode layer 12 and the third electrode layer 16 are silver (Ag) layers with a thickness of several hundreds of nanometers (nm) and are formed by a sputtering method. Although not illustrated in the drawings, a texture pattern may be formed on the surface of the first electrode layer 12 in order to diffuse incident light and increase the amount of light absorbed by the photoelectric conversion layer 13. In this embodiment, a silver (Ag) electrode is used as the first electrode layer 12, but the invention is not limited thereto. For example, a film laminate obtained by forming titanium dioxide (TiO₂) with resistance to plasma on the surface of a silver (Ag) electrode, a tin dioxide (SnO₂) film, or a zinc oxide (ZnO) film may be used as the first electrode layer 12. In addition, a material capable of forming the optimal texture pattern may be used to form the first electrode layer 12.

The photoelectric conversion layer 13 is a thin-film semiconductor layer. In this embodiment, the photoelectric conversion layer 13 has a double layer tandem structure of amorphous silicon (a-Si) and amorphous silicon germanium (a-SiGe). However, the invention is not limited thereto. For example, the photoelectric conversion layer 13 may be made of amorphous silicon carbide (a-SiC), amorphous silicon oxide (a-SiO), amorphous silicon nitride (a-SiN), microcrystalline silicon (μc-Si), microcrystalline silicon germanium (μc-SiGe), microcrystalline silicon carbide (μc-SiC), microcrystalline silicon oxide (μc-SiO), or microcrystalline silicon nitride (μc-SiN). In addition, the photoelectric conversion layer 13 may be made of a compound-based material or an organic material. Each layer of the photoelectric conversion layer 13 may be formed by, for example, a plasma chemical vapor deposition (plasma CVD) method, a sputtering method, a vapor deposition method, a catalytic chemical vapor deposition (Cat-CVD) method, or a photochemical vapor deposition (photo-CVD) method.

The second electrode layer 14 is a transparent electrode layer. An indium tin oxide (ITO) film formed by the sputtering method is used as the second electrode layer 14. However, the invention is not limited thereto. For example, a tin dioxide (SnO₂) film or a zinc oxide (ZnO) film may be used as the second electrode layer 14.

The fourth electrode layer 17 is a low-resistance conductive film such as a metal film. In this embodiment, a nickel (Ni) film formed by the sputtering method is used as the fourth electrode layer 17. However, the invention is not limited thereto. The fourth electrode layer 17 may be made of a metal material other than nickel.

The current collection holes 19 are distributed all over the second electrode layer 14 of each unit cell (UC). Six connection holes 20 are provided in each unit cell (UC) (three connection holes 20 are provided in a line on one side of the second electrode layer 14). The current collection holes 19 and the connection holes 20 are formed by a mechanical means such as punching. In this embodiment, the current collection holes 19 and the connection holes 20 have a circular shape, and the diameter of each current collection hole 19 is smaller than that of each connection hole 20. As such, the current collection holes 19 with a diameter smaller than that of the connection holes 20 are arranged so as to be distributed all over the second electrode layer 14. Therefore, power loss in the second electrode layer 14 is reduced, and a reduction in the power generation area of the current collection holes 19 is prevented. However, the invention is not limited thereto. The shapes, sizes, and number of current collection holes 19 and connection holes 20 may appropriately vary depending on the specifications of the thin-film solar cell 10.

A method of manufacturing the thin-film solar cell 10 according to this embodiment is basically the same as the method of manufacturing the thin-film solar cell according to the related art illustrated in FIGS. 10A to 10G. Therefore, description thereof will not be repeated.

Next, some of the characteristics of the thin-film solar cell 10 according to this embodiment will be described in comparison with the thin-film solar cell (see FIG. 9) according to the related art.

First, one of the characteristics of the thin-film solar cell 10 is that the first linearly removed portion 21 in each layer provided on the front surface of the insulating substrate 11 has a linear shape, similar to the thin-film solar cell according to the related art, but the second linearly removed portion 22 in each layer provided on the rear surface of the insulating substrate 11 has a bent portion 22a. Specifically, in this embodiment, the second linearly removed portion 22 has a bent structure that is bent two times at an angle of 90° on both sides in the leftward-rightward direction of FIG. 1, in order to align the position of the unit photoelectric conversion portion with the position of the unit rear electrode layer in each unit cell (UC), with the insulating substrate 11 interposed therebetween. That is, in the this embodiment, the second linearly removed portion 22 includes the bent portion 22a such that the unit photoelectric conversion portion and the unit rear electrode layer forming each unit cell (UC) are aligned with each other with the insulating substrate 11 interposed therebetween.

In this way, in each unit cell (UC), the position where the current collection holes 19 are formed is not limited (the position does not deviate), and it is possible to form a desired number of current collection holes 19 at desired positions according to, for example, the manufacturing conditions of the thin-film solar cell. Therefore, it is possible to improve current collection efficiency.

The shape of the second linearly removed portion 22 is not limited to that in this embodiment. For example, the second linearly removed portion 22 may have an obliquely bent structure or may have a shape including a curve. In addition, the second linearly removed portion 22 may be formed in a straight line and the first linearly removed portion 21 may have a bent portion. Alternatively, each of the first linearly removed portion 21 and the second linearly removed portion 20 may have a bent portion.

Another characteristic of the thin-film solar cell 10 according to this embodiment is that multiple current collection holes 19 are arranged so as to be distributed all over the second electrode layer 14 of each unit cell (UC). In this way, it is possible to significantly reduce the length of a current path in the second electrode layer 14 with high resistance and reduce power loss (current collection loss) in the second electrode layer 14.

In this embodiment, the multiple current collection holes 19 are arranged at substantially equal intervals in a matrix in the range of the second electrode layer 14 of each unit cell (UC). As such, since the current collection holes 19 are substantially uniformly arranged in the entire second electrode layer 14, it is possible to significantly reduce the length of the current path in the second electrode layer 14 with high resistance and improve the uniformity of current flow. Therefore, it is possible to effectively reduce current collection loss.

In this embodiment, the multiple current collection holes 19 are arranged in a houndstooth shape in the second electrode layer 14 of each unit cell (UC). In this case, columns of the current collection holes 19 that are arranged at equal intervals in the width direction of the thin-film solar cell 10 are provided to be arranged at equal intervals in a direction orthogonal to the width direction. Further, odd-numbered columns of the current collection holes 19 and even-numbered columns of the current collection holes 19 deviate from each other by half of the pitch between the current collection holes 19 in the width direction. That is, it is preferable that the multiple current collection holes 19 be arranged in a houndstooth shape.

However, when a linearly removed portion having a bent portion, such as the second linearly removed portion 22, is formed by, for example, laser patterning, two-dimensional laser scanning in the X-Y direction is needed. That is, it is necessary to change the traveling direction of the laser beam during patterning. In this case, in order to ensure the processing accuracy of the bent portion, it is necessary to reduce the speed of the laser patterning. As a result, a laser acceleration and deceleration region is generated.

In the laser patterning, a laser pulse is applied at a constant frequency to remove a member in an irradiation portion. Therefore, when the laser pulse with intensity higher than a necessary level is applied to the same portion, the periphery of the irradiation portion is damaged. In the first embodiment, when the bent portion 22a of the second linearly removed portion 22 is processed, the laser acceleration and deceleration region is generated, and the number of laser pulses applied in the laser acceleration and deceleration region is more than that in the other regions. As a result, there is a concern that the photoelectric conversion layer 13 provided on the front surface of the substrate will be damaged and leakage will occurs. When excessive energy is incident on the photoelectric conversion layer 13 provided on the front surface of the substrate, the photoelectric conversion layer 13 is crystallized or damaged and the first electrode layer 12 and the second electrode layer 14 are electrically connected to each other, which results in the leakage. Therefore, when the first linearly removed portion 21 has a bent portion, the leakage is more likely to occur.

In order to solve the above-mentioned problem, a method of shielding the laser beam by using, for example, a shutter in the laser acceleration and deceleration region is considered. However, in this method, the cost of a laser processing apparatus increases, and the opening/closing speed of the shutter does not catch up with the oscillating frequency of the laser, which makes it difficult to ensure processing accuracy. In methods other than the laser processing, for example, in a process using an ultrasonic transducer or a sandblasting process, when the bent portion is formed, a processing acceleration and deceleration region is generated and excessive force or energy is applied to the photoelectric conversion layer 13. As a result, similar to the laser processing, there is a concern that the photoelectric conversion layer 13 will be damaged and leakage will occur.

In order to prevent the leakage and concern for the leakage, the thin-film solar cell 10 according to the first embodiment is improved as follows (second to fifth embodiments). The following embodiments can be applied to all thin-film solar cells in which the linearly removed portion has a bent portion, regardless of the purpose of bending of the linearly removed portion formed in each layer on the substrate.

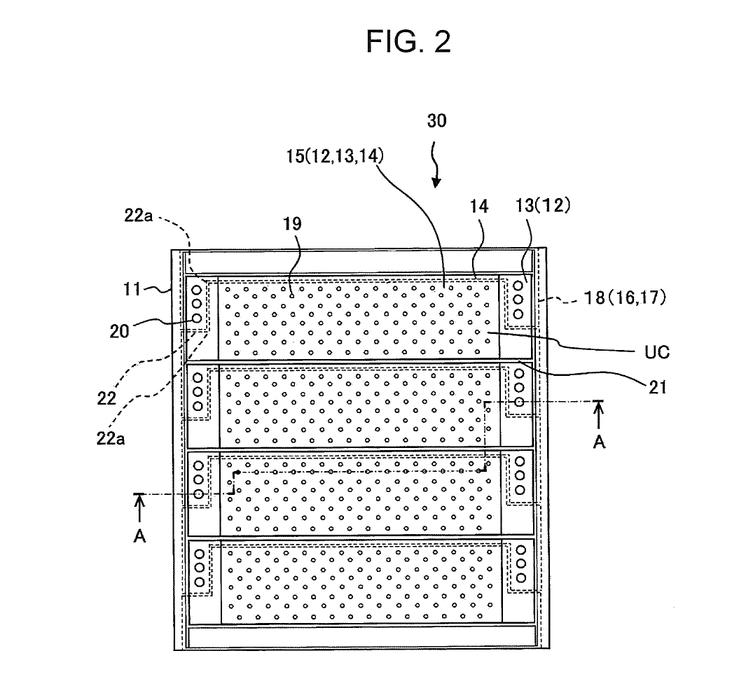

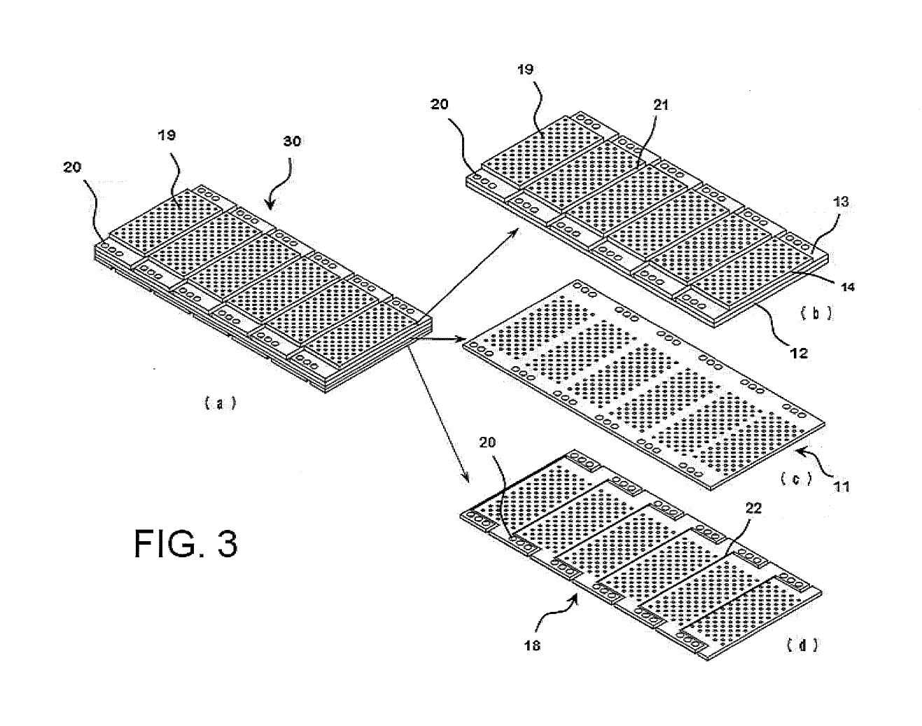

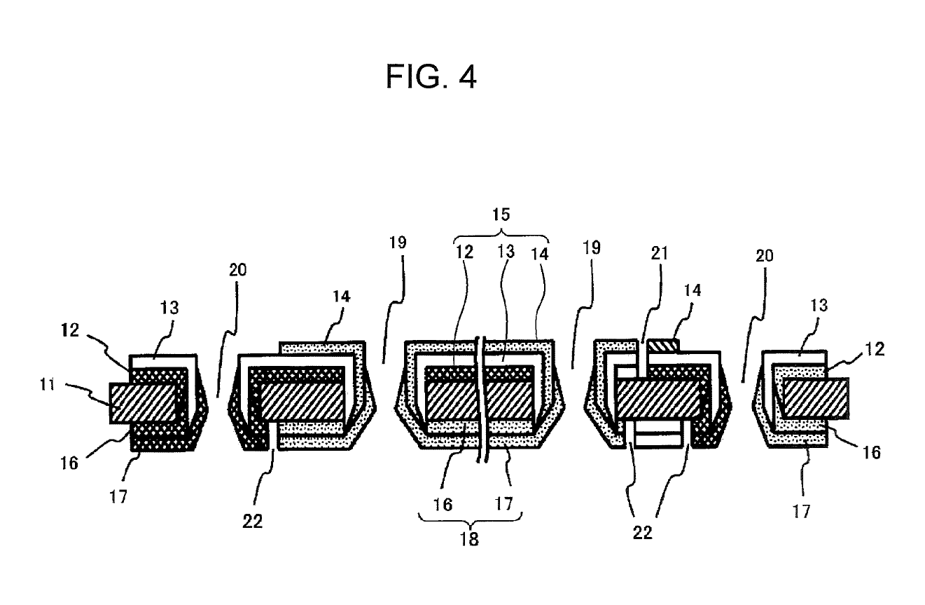

FIG. 2 is a plan view illustrating a thin-film solar cell 30 according to a second embodiment of the invention. FIG. 3 includes exploded perspective views (a) to (d) of FIG. 2. FIG. 4 is a cross-sectional view taken along the line IV-IV of FIG. 2. In FIGS. 2 to 4, components having the same functions as those illustrated in FIG. 1 are denoted by the same reference numerals. A method of manufacturing the thin-film solar cell 30 according to this embodiment is basically the same as that of manufacturing the thin-film solar cell according to the related art illustrated in FIGS. 10A to 10G, and thus description thereof will not be repeated. In FIG. 3, exploded view (a) illustrates the overall structure of the thin-film solar cell 30, and exploded view (b) illustrates a laminate structure of a first electrode layer 12, a photoelectric conversion layer 13, and a second electrode layer formed on an insulating substrate 11. In addition, exploded view (c) of FIG. 3 illustrates the insulating substrate 11, and exploded view (d) of FIG. 3 illustrates a rear electrode layer 18 formed on the rear surface of the insulating substrate 11.

The thin-film solar cell 30 according to the second embodiment differs from the thin-film solar cell 10 according to the first embodiment in that the bent portion 22a of the second linearly removed portion 22 is disposed in a region in which the second electrode layer 14 is not formed, which is provided in the vicinity of a portion where the connection holes 20 are formed, in a plan view. The region in which the second electrode layer 14 is not formed includes a region of the front surface of the insulating substrate 11 in which the second electrode layer 14 is not formed, and a region of the rear surface of the insulating substrate 11 corresponding to the region. In this embodiment, the bent portion 22a is formed in the region of the rear surface of the insulating substrate 11.

In this embodiment, the second linearly removed portion 22 includes the bent portion 22a. However, instead of or in addition to the second linearly removed portion 22, when the first linearly removed portion 21 includes a bent portion, the bent portion of the first linearly removed portion 21 may be disposed in the region in which the second electrode layer 14 is not formed, which is provided in the vicinity of the portion where the connection holes 20 are formed.

According to this structure, during the manufacture of the thin-film solar cell, for example, even when the photoelectric conversion layer is crystallized or damaged in the bent portion of the linearly removed portion by, for example, laser processing, a leakage path is not formed due to the electrical connection between the first electrode layer and the second electrode layer since the bent portion is disposed in the region in which the second electrode layer is not formed.

The following Table 1 shows I-V characteristics of the thin-film solar cell 10 according to the first embodiment and the thin-film solar cell 30 according to the second embodiment. The I-V characteristics are measured using a solar simulator under the condition of a solar radiation intensity of 1 SUN (1000 W/m2) after the manufactured thin-film solar cell is subjected to a reverse bias treatment. In the following Table 1, the values of the open voltage (Voc), the short-circuit current (Isc), the fill factor (FF), and the heat exchanger effectiveness (Eff) of the thin-film solar cell 30 according to the second embodiment are normalized to 1.

TABLE 1

| | Voc | Isc | FF | Eff |
|---|---|---|---|---|
| First | 0.98 | 1.0 | 0.98 | 0.96 |
| embodiment | | | | |
| Second | 1.0 | 1.0 | 1.0 | 1.0 |
| embodiment | | | | |

As can be seen from Table 1, the thin-film solar cell 10 according to the first embodiment has a low open voltage (Voc), a low fill factor (FF), and a low output, as compared to the thin-film solar cell 30 according to the second embodiment. It is considered that this is because there is a relatively large amount of leakage that cannot be removed even when the thin-film solar cell 10 according to the first embodiment is subjected to the reverse bias treatment. The two thin-film solar cells are manufactured by the same process, but are different from each other in the formed positions of the bent portion 22a of the second linearly removed portion 22. Therefore, in the thin-film solar cell 10 according to the first embodiment, it is considered that leakage occurs near the bent portion 22a of the second linearly removed portion 22. Therefore, the thin-film solar cell 30 according to the second embodiment capable of reliably preventing the leakage is preferable.

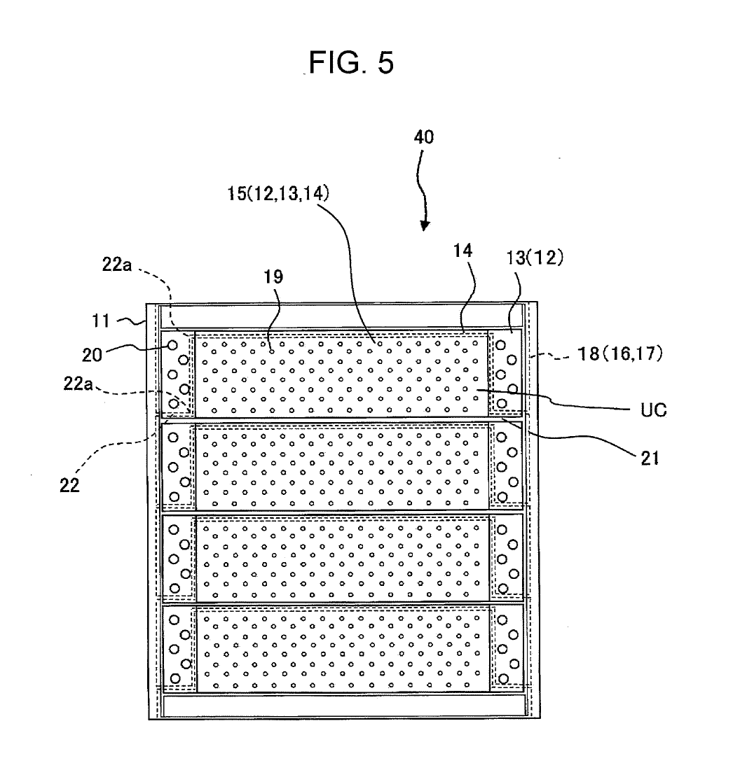

FIG. 5 is a plan view illustrating a thin-film solar cell 40 according to a third embodiment of the invention. The thin-film solar cell 40 according to the third embodiment differs from the thin-film solar cell 30 according to the second embodiment in that the number of connection holes 20 is larger and connection holes 20 are arranged in a zigzag, not in a straight line. Specifically, the connection holes 20 are substantially uniformly arranged in an overlap region between a first electrode layer 12 of one of two adjacent unit cells (UC) and a portion of the third electrode layer 16 of the other unit cell. According to this structure, it is possible to improve the uniformity of current flow between adjacent unit cells and reduce power collection loss.

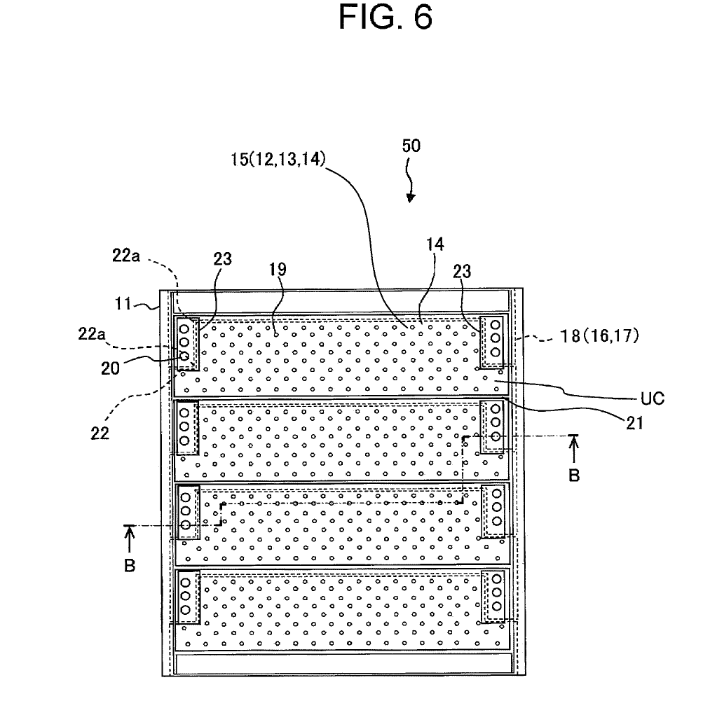

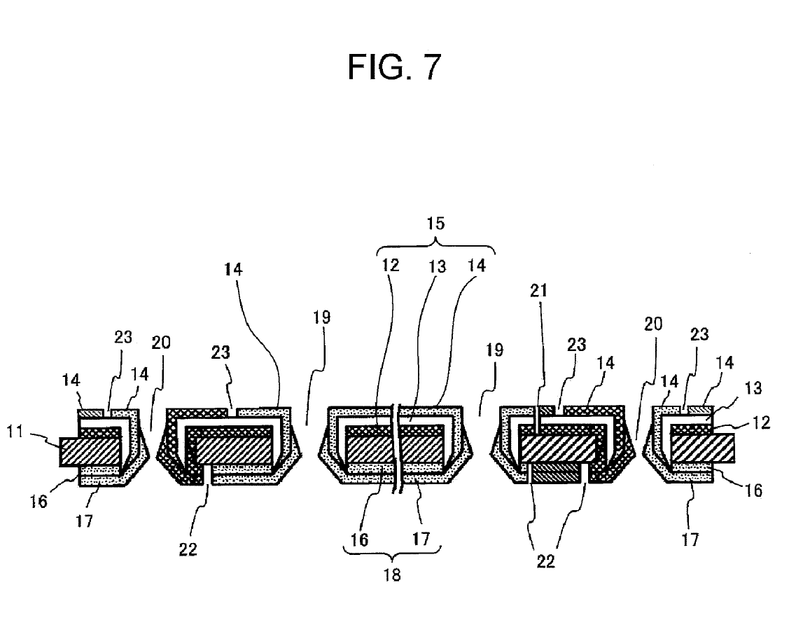

FIG. 6 is a plan view illustrating a thin-film solar cell 50 according to a fourth embodiment of the invention, and FIG. 7 is a cross-sectional view taken along the line VII-VII of FIG. 6. The thin-film solar cell 50 according to the fourth embodiment differs from the thin-film solar cell 30 according to the second embodiment in that a second electrode layer 14 is also formed near the portion in which connection holes 20 are formed, the second electrode layer 14 electrically isolates a region in which connection holes 20 are formed from a region in which the connection holes 20 are not formed, and a bent portion 22a of a second linearly removed portion 22 is disposed in the region in which the connection holes 20 are formed in a plan view. The region in which the connection holes 20 are formed includes a region inside an isolating portion 23 that electrically isolates the second electrode layer 14 on the front surface of an insulating substrate 11 and a region of the rear surface of the insulating substrate 11 corresponding to the region. In this embodiment, the bent portion 22a is formed in the region of the rear surface of the insulating substrate 11. In this embodiment, the second linearly removed portion 22 includes the bent portion 22a. However, instead of or in addition to the second linearly removed portion 22, when a first linearly removed portion 21 includes a bent portion, the bent portion of the first linearly removed portion 21 may be disposed in the region in which the connection holes 20 are formed.

The thin-film solar cell 50 according to this embodiment can be manufactured as follows. In the process (FIG. 10E) of forming the second electrode layer in the method of manufacturing the thin-film solar cell according to the related art, the second electrode layer 14 is formed without using a mask, the periphery of a portion in which the connection holes 20 are formed is linearly remove by, for example, a laser patterning process to form the isolating portion 23. When the second electrode layer 14 is formed, a mask for forming the separation portion 23 may be used.

According to this structure, even when a photoelectric conversion layer 13 is crystallized or damaged in the bent portion of the linearly removed portion due to, for example, laser processing during the manufacture of the thin-film solar cell, leakage does not occur in, for example, a damaged portion of the photoelectric conversion layer 13 since the second electrode layer 14 in which the bent portion is formed is electrically connected to the first electrode layer 12 via the connection holes 20 and the second electrode layer 14 is divided into a region including the connection holes 20 and a region that does not include the connection hole 20 by the isolating portion 23. As a result of measurement, the thin-film solar cell 50 according to this embodiment has the I-V characteristics with a small amount of leakage, similar to the thin-film solar cell 30 according to the second embodiment.

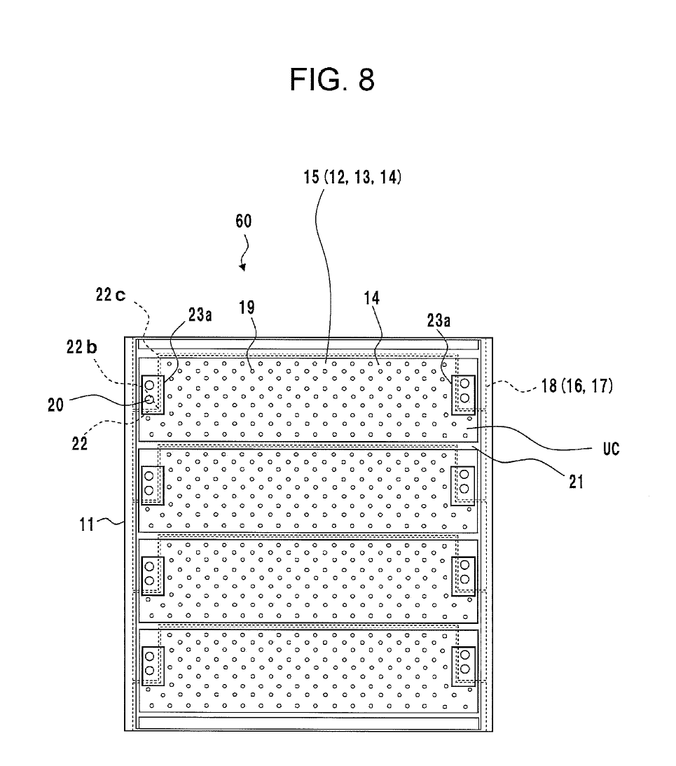

FIG. 8 is a plan view illustrating a thin-film solar cell 60 according to a fifth embodiment of the invention. The thin-film solar cell 60 according to the fifth embodiment differs from the thin-film solar cell 50 according to the fourth embodiment illustrated in FIG. 6 in that an area of an isolating portion 23a is small, a bent portion 22b is disposed in the isolating portion 23a provided in a region in which connection holes 20 are formed, and a bent portion 22c is disposed in a region in which a first linearly removed portion 21 is formed. According to this structure, it is also possible to prevent the occurrence of leakage.

It will be apparent to one skilled in the art that the manner of making and using the claimed invention has been adequately disclosed in the above-written description of the exemplary embodiments taken together with the drawings. Furthermore, the foregoing description of the embodiments according to the invention is provided for illustration only, and not for limiting the invention as defined by the appended claims and their equivalents.

It will be understood that the above description of the exemplary embodiments of the invention are susceptible to various modifications, changes and adaptations, and the same are intended to be comprehended within the meaning and range of equivalents of the appended claims.

What is claimed is:

1. A thin-film solar cell, comprising:
an insulating substrate; and
a plurality of unit solar cells formed on the insulating substrate, each of the plurality of unit solar cells including:
a photoelectric conversion portion including a first electrode layer, a photoelectric conversion layer, and a second transparent electrode layer, sequentially formed on a front surface of the insulating substrate, and
a rear electrode layer formed on a rear surface of the insulating substrate, the rear electrode layer being electrically connected to the second electrode layer via a plurality of current collection holes passing through the insulating substrate,
wherein a portion of the first electrode layer of one of two adjacent unit solar cells, taken from a plan view, overlaps a portion of the rear electrode layer of the other of the two adjacent unit solar cells with the insulating substrate interposed therebetween, at least one of said portion of the first electrode layer and said portion of the rear electrode layer forming an extending portion which extends outward from either the remaining portion of the first electrode layer or the remaining portion of the rear electrode layer, and
wherein the first electrode layer of the one of the two adjacent unit solar cells is electrically connected to the rear electrode layer of the other of the two adjacent unit solar cells via at least one connection hole passing through the insulating substrate and being connected to the extending portion, such that the plurality of unit solar cells are connected in series to one another.

2. The thin-film solar cell according to claim 1, wherein the front surface of the insulating substrate includes a first portion on which the photoelectric conversion portion is not formed, and the rear surface of the insulating substrate includes a second portion on which the rear electrode layer is not formed.

3. The thin-film solar cell according to claim 2, wherein the first portion has a linear shape.

4. The thin-film solar cell according to claim 2, wherein the second portion has a linear shape.

5. The thin-film solar cell according to claim 2, wherein the first portion includes at least one bent portion.

6. The thin-film solar cell according to claim 2, wherein the second portion includes at least one bent portion.

7. The thin-film solar cell according to claim 6, wherein the bent portion includes a bent structure that is bent two times at the angle of 90° on both sides thereof in leftward and rightward directions, respectively.

8. The thin-film solar cell according to claim 1, wherein the plurality of current collection holes are arranged at substantially equal intervals in a matrix in a range of the second electrode layer of each unit solar cell.

9. The thin-film solar cell according to claim 8, wherein the plurality of current collection holes are arranged in a houndstooth shape such that
the plurality of current collection holes are arranged at substantially equal intervals in a width direction of the thin-film solar cell, and
odd-numbered columns of the plurality of current collection holes and even-numbered columns of the plurality of current collection holes deviate from each other by half of a pitch between the current collection holes in the width direction.

10. The thin-film solar cell according to claim 1, wherein the first electrode layer includes a region free of the second electrode layer, which is provided near the at least one connection hole, and
the extending portion is disposed in the region free of the second electrode layer.

11. The thin-film solar cell according to claim 10, wherein the region free of the second electrode layer includes a first region of the front surface of the insulating substrate in which the second electrode layer is not formed, and
a second region of the rear surface of the insulating substrate, corresponding to the first region.

12. The thin-film solar cell according to claim 1, wherein
the rear electrode layer includes a third electrode layer and a fourth electrode layer, and
the at least one connection hole is substantially uniformly arranged in a region in which the first electrode layer of the one of the two adjacent unit cells overlaps the third electrode layer of the other unit cell of the two adjacent unit cells.

13. The thin-film solar cell according to claim 12, wherein the at least one connection hole is arranged in a zigzag pattern.

14. The thin-film solar cell according to claim 1, wherein
the second electrode layer includes a first region in which the connection holes are provided and a second region in which current collection holes are provided,
the first region is electrically isolated from the second region, and
the extending portion is disposed in the first region.

15. The thin-film solar cell according to claim 14, wherein the first region includes a region enclosed by an isolation portion that electrically isolates the second electrode layer from a corresponding region of the rear surface of the insulating substrate.

16. The thin-film solar cell according to claim 14, wherein the rear surface of the insulating substrate includes an electrode-free portion on which the rear electrode layer is not formed, and the electrode-free portion includes a bent portion that is disposed, taken from a plan view, in a position to overlap the first region.

17. The thin-film solar cell according to claim 1, wherein
the second electrode layer is additionally formed near a connection region in which the at least one connection hole is formed,
the connection region includes a region enclosed by an isolation portion that electrically isolates the second electrode layer from a corresponding region of the rear surface of the insulating substrate,
a first bent portion is disposed in the isolation portion,
the photoelectric conversion portion is linearly removed by a first linearly removed portion, and
a second bent portion is disposed in a region in which the first linearly removed portion is formed.

18. The thin-film solar cell according to claim 1, wherein the extending portion is formed by said portion of the rear electrode layer.

19. The thin-film solar cell according to claim 1, wherein the extending portion is formed by said portion of the first electrode layer.

20. The thin-film solar cell according to claim 1, wherein:
taken from a plan view, in each unit solar cell, the photoelectric conversion portion and the rear electrode layer respectively have an upper end and a lower end opposite to the upper end, the lower end facing a further upper end of an adjacent one of the unit solar cells; and
taken from a plan view, in each unit solar cell, the upper end of the photoelectric conversion portion is aligned with the upper end of the rear electrode layer, and the lower end of the photoelectric conversion portion is aligned with the lower end of the rear electrode layer.
